(19) United States
(12) Patent Application Publication
(10) Pub. No.: US 2019/0154763 A1
(43) Pub. Date: May 23, 2019

(54) HIGH CAPACITY BATTERY BALANCER

(71) Applicant: Midtronics, Inc., Willowbrook, IL (US)

(72) Inventor: Kevin I. Bertness, Batavia, IL (US)

(21) Appl. No.: 16/253,526

(22) Filed: Jan. 22, 2019

Related U.S. Application Data
(63) Continuation-in-part of application No. 16/021,538, filed on Jun. 28, 2018.
Application No. 16/021,538 is a continuation of application No. 14/039,746, filed on Sep. 27, 2013, now abandoned.
Application No. 14/039,746 is a continuation of application No. 13/152,711, filed on Jun. 3, 2011, now abandoned.
Application No. 13/152,711 is a continuation of application No. 12/894,951, filed on Sep. 30, 2010, now Pat. No. 8,738,309.
Application No. 12/894,951 is a continuation-in-part of application No. 16/056,991, filed on Aug. 7, 2018.
Application No. 16/056,991 is a division of application No. 13/827,128, filed on Mar. 14, 2013, now Pat. No. 10,046,649.
(60) Provisional application No. 62/620,659, filed on Jan. 23, 2018.
(60) Provisional application No. 61/351,017, filed on Jun. 3, 2010.
(60) Provisional application No. 61/665,555, filed on Jun. 28, 2012.

(51) Int. Cl. G01R 31/385; B60L 50/60; B60L 3/00; B60L 58/18; B60L 53/65; B60L 53/80; B60L 50/62; B60L 58/21; B60L 3/12; H01M 10/42; H01M 10/54

(52) U.S. Cl. CPC G01R 31/385; Y02T 10/6217; B60L 3/0046; B60L 58/18; B60L 53/65; B60L 53/80; B60L 50/62; B60L 58/21; B60L 3/12; H01M 10/4207; H01M 10/4285; H01M 10/54; Y02T 10/7011; Y02T 90/121; B60L 2240/545; Y02T 90/163; Y02T 90/14; Y02T 90/128; Y02T 90/124; Y02T 10/7077; Y02T 10/7072; Y02T 10/7061; H01M 2220/20; Y02T 90/169; Y04S 30/14; Y02W 30/84; B60L 50/66

(57) ABSTRACT

An apparatus for balancing charge of a battery in a battery pack includes a plurality of power supplies configured to be selectively coupled to the battery and a plurality of electrical loads configured to be electrically coupled to the battery. Test circuitry is configured to measure an amount of charge of the battery. Control circuitry selectively controls a voltage applied to the battery by the plurality of power supplies and a load applied to the battery by the plurality of electrical loads based upon a measured amount of charge of the battery.

A method and apparatus for repairing or testing a used battery pack from an electric vehicle includes optionally removing the battery pack from the vehicle. Batteries within the pack are balanced such that they have similar states of charge.

The present invention includes a battery pack maintenance device for performing maintenance on battery packs of hybrid and/or electrical vehicles (referred herein generally as electric vehicles). In various embodiments, the device includes one or more loads for connecting to a battery pack for use in discharging the battery pack, and/or charging circuitry for use in charging the battery pack. Input/output circuitry can be provided for communicating with circuitry of in the battery pack and/or circuitry of the vehicle.

### CROSS-REFERENCE TO RELATED APPLICATION

The present application is based on and claims the benefit of US provisional patent application Ser. No. 62/620,659, filed Jan. 23, 2018, the present application is also a Continuation-in-Part of U.S. Ser. No. 16/021,538, filed Jun. 28, 2018, which is Continuation of U.S. Ser. No. 14/039,746, filed Sep. 27, 2013, which is a Continuation of U.S. Ser. No. 13/152,711, filed Jun. 3, 2011 which claims the benefit of U.S. provisional patent application Ser. No. 61/351,017, filed Jun. 3, 2010, and is a Continuation of U.S. patent application Ser. No. 12/894,951, filed Sep. 30, 2010, the present application is also a Continuation-In-Part of U.S. Ser. No. 16/056,991, filed Aug. 7, 2018, which is a Divisional of U.S. Ser. No. 13/827,128, filed Mar. 14, 2013, which claims benefit of U.S. provisional patent application Ser. No. 61/665,555, filed Jun. 28, 2012, the contents of which are hereby incorporated by reference in their entirety.

### BACKGROUND OF THE INVENTION

The present invention relates to electric vehicles of the types which use battery packs for storing electricity. More specifically, the present invention relates to maintenance of such battery packs.

Traditionally, automotive vehicles have used internal combustion engines as their power source. Petroleum as a source of power. However, vehicles which also store energy in batteries are finding widespread use. Such vehicle can provide increased fuel efficiency and can be operated using alternative energy sources.

Some types of electric vehicles are completely powered using electric motors and electricity. Other types of electric vehicles include an internal combustion engine. The internal combustion engine can be used to generate electricity and supplement the power delivered by the electric motor. These types of vehicles are known as “hybrid” electric vehicles.

Operation of an electric vehicle requires a source of electricity. Typically, electric vehicles store electricity in large battery packs which consist of a plurality of batteries. These batteries may be folioed by a number of individual cells or may themselves be individual cells depending on the configuration of the battery and battery pack. The packs are large and replacement can be expensive.

It can be appreciated that batteries for electric vehicles are becoming ever larger in capacity. It is desired to create a service tool that can service these batteries in a short period of time, reduce the skill level of the technician required, and improve the quality of the service repair, while maintaining a cost effective solution. Further, the frequency of use of these tools is still rather low, so it is desirable to provide as much guidance as possible to the technician who may only perform these procedures every few months.

### SUMMARY OF THE INVENTION

An apparatus for balancing charge of a battery in a battery pack includes a plurality of power supplies configured to be selectively coupled to the battery and a plurality of electrical loads configured to be electrically coupled to the battery. Test circuitry is configured to measure an amount of charge of the battery. Control circuitry selectively controls a voltage applied to the battery by the plurality of power supplies and a load applied to the battery by the plurality of electrical loads based upon a measured amount of charge of the battery.

A method and apparatus for repairing or testing a used battery pack from an electric vehicle includes optionally removing the battery pack from the vehicle. Batteries within the pack are balanced such that they have similar states of charge.

The present invention includes a battery pack maintenance device for performing maintenance on battery packs of hybrid and/or electrical vehicles (referred herein generally as electric vehicles). In various embodiments, the device includes one or more loads for connecting to a battery pack for use in discharging the battery pack, and/or charging circuitry for use in charging the battery pack. Input/output circuitry can be provided for communicating with circuitry of in the battery pack and/or circuitry of the vehicle.

### BRIEF DESCRIPTION OF THE DRAWINGS

FIG. 1 is a simplified block diagram of an electric vehicle.

FIG. 2 is simplified schematic diagram of a battery pack for use in the electric vehicle of FIG. 1.

FIG. 3 is a block diagram of a device in accordance with one example embodiment of the present invention.

FIG. 4 is a perspective view of a battery balancer in accordance with one embodiment.

FIG. 5A is a simplified schematic diagram showing a high current parallel connection to a battery.

FIG. 5B is a simplified schematic diagram showing a high voltage series connection to a battery.

FIG. 6 is a perspective view of a cable used to a battery balancer to a battery of a vehicle.

FIG. 7 is a simplified schematic diagram showing discharge circuitry.

FIG. 8 is a diagram showing electrical connections connecting to a battery module within a battery pack.

### DETAILED DESCRIPTION OF ILLUSTRATIVE EMBODIMENTS

As discussed in the background section, battery packs used with electric vehicles are able to store large amounts of energy. The battery packs are large and difficult to work on and test because of the high voltages involved. Further, the battery packs are expensive. In one aspect, the present application recognizes that a single bad battery within the battery pack can reduce the capabilities of the overall battery pack. A bad battery, or batteries within a pack that are not balanced, can reduce the amount of energy the battery pack can store, reduce the rate at which the battery pack can be recharged and cause other batteries with in the battery pack to drain prematurely. As used herein, balanced refers to batteries that have similar states of charge and/or capacity.

In one aspect of the present invention, a battery pack is removed from the electric vehicle whereby maintenance can be performed on it. More specifically, individual batteries of the pack tested. A refurbished battery pack is made by preparing a new set of batteries for use in creating a refurbished battery pack. The new set of batteries is formed from used batteries from previously used battery pack(s) along with one or more additional batteries. The set of batteries used to form the refurbished battery pack are selected such that they have at least one test result which is similar to the others. The refurbished battery pack can then placed in an electric vehicle and be used as a source of power for the vehicle. The refurbished battery pack can also be made by balancing batteries within the pack using the power supply and/or resistive loads discussed herein.

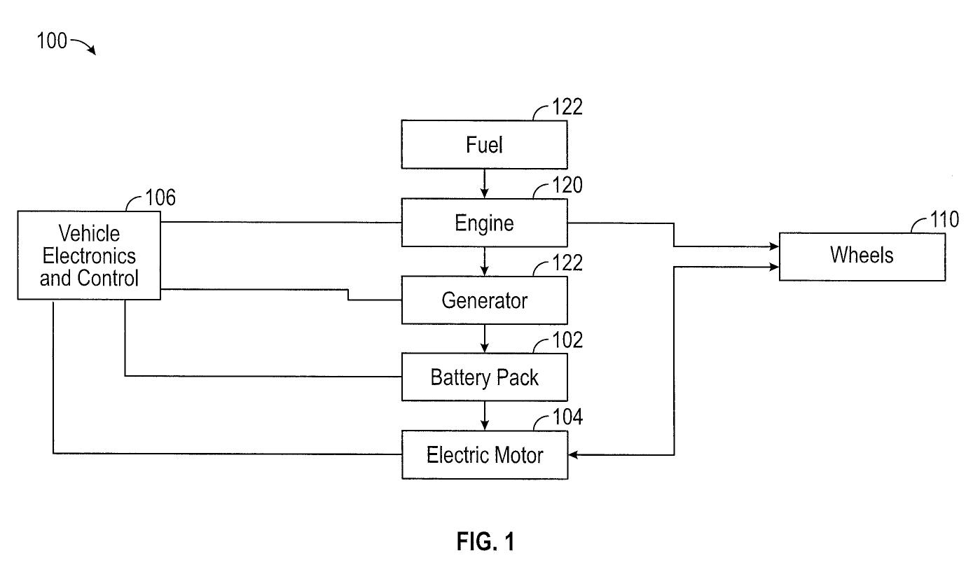

FIG. 1 is a simplified block diagram of an electric vehicle 100. Electric vehicle 100 can be configured to operate solely based upon electric power, or may include an internal combustion engine. Vehicle 100 includes a battery pack 102 and at least one electric motor 104. Vehicle electronics and control system 106 couples to the battery pack and electric motor and is configured to control their operation. Wheels 110 of vehicle 100 are configured to propel the vehicle in response to a mechanical input from electric motor 104. Electric motor 104 operates using energy drawn from the battery 102. In some configurations a regenerative braking system can be used in which a braking energy is recovered from the wheels 110 by the electric motor 104 or other equipment. The recovered energy can be used to recharge the battery pack 102.

FIG. 1 also shows optional components of vehicle 100. These optional components allow the vehicle 100 to operate as “hybrid” vehicle. In such a configuration, an internal combustion engine 120 is provided which operates using, for example, petroleum based fuel 122. The engine 120 can be configured to directly mechanically drive the wheels 110 and/or an electric generator 122. The electric generator 122 can be configured to charge the battery pack 102 and/or provide electrical power directly to electric motor 104.

The battery pack 102 is a critical component of the electric vehicle 100. Operation of the battery pack 102 will determine the efficiency of the vehicle, the overall range of the vehicle, the rate at which the battery pack 102 can be charged and the rate at which the battery pack 102 can be discharged.

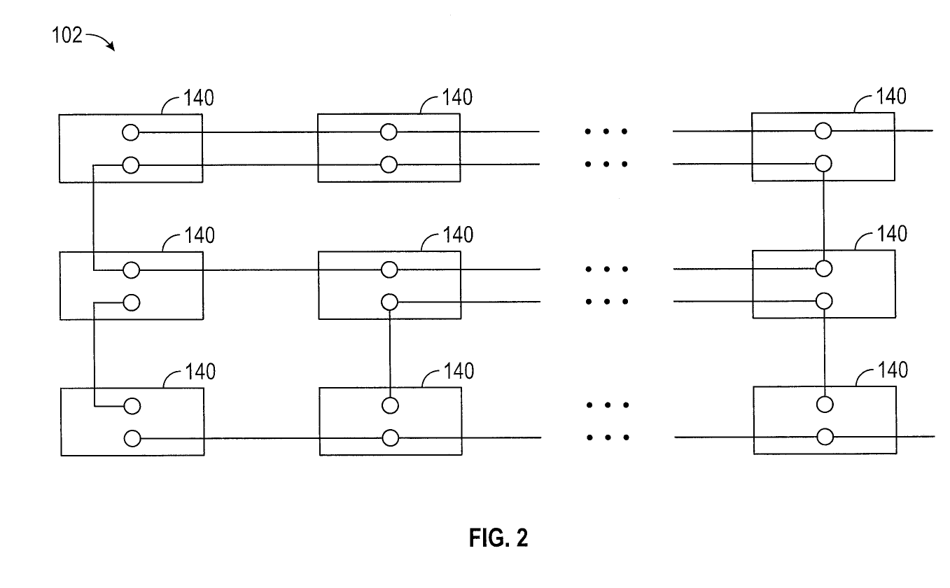

FIG. 2 is a simplified diagram of an example configuration of battery pack 102. In FIG. 2, a plurality of individual batteries 140 are shown connected in series and parallel. Each of the individual batteries 140 may comprise a single cell or may comprise multiple cells connected in series and/or parallel. These may be removable battery modules formed by a single cell or a group of cells. If elements 140 are a group of cells, in some configurations individual connections may be available within the battery and used in accordance with the invention.

During the lifetime of vehicle 100, the battery pack 102 will degrade with time and use. This degradation may be gradual, or may occur rapidly based upon a failure of a component within the pack 102. When such a failure occurs, or when the pack has degraded sufficiently, the entire battery pack 102 is typically replaced. The battery pack 102 is one of the primary components of electric vehicle 100 and its replacement can be very expensive. In one aspect, the present invention is directed to performing maintenance on battery pack 102. The maintenance can be performed after the battery pack has failed, or prior to the failure of the battery pack. The maintenance can include balancing batteries within the pack.

In one aspect, the invention includes the recognition that the failure, degradation, or impending failure of battery pack 102 may be due to the failing or degrading of one or more of the individual batteries 140 within the pack 102. In such a case, the battery pack 102 can be refurbished or otherwise repaired by identifying the failed, failing, or degraded batteries 140 and replacing them with operable batteries 140. In another aspect, the present invention includes the recognition that the simple replacement of a faulty battery 140 in a battery pack 102 may not provide the optimum configuration for the repaired or refurbished battery pack 102. More specifically, a “new” battery 140 used to replace a “bad” battery 140 within the battery pack 102 will introduce a battery which is not balanced with respect to other batteries 140 in the pack 102. This unbalanced battery 140 may cause further deterioration in the battery pack 102. Thus, in one aspect, the present invention includes selecting batteries 140 which have a similar characteristic or measured parameter for replacing bad batteries 140 within a battery pack 102 as well as charging or discharging batteries to achieve balance.

In one aspect, the present invention provides a method and apparatus in which batteries 140 for use in battery packs 102 are sorted and selected for replacement based upon measured parameters. The measured parameters can be selected such that they are in agreement with one another within a desired range. Example parameters include static parameters in which a static property of a battery is measured using a static function as well as dynamic parameters in which a property of a battery is measured using a dynamic function. Example parameters include dynamic parameters such as conductance resistance, admittance, impedance, etc., as well as static equivalents. Load testing based parameters may also be employed. Other example parameters include battery capacitance, battery state of charge, battery voltage, and others.

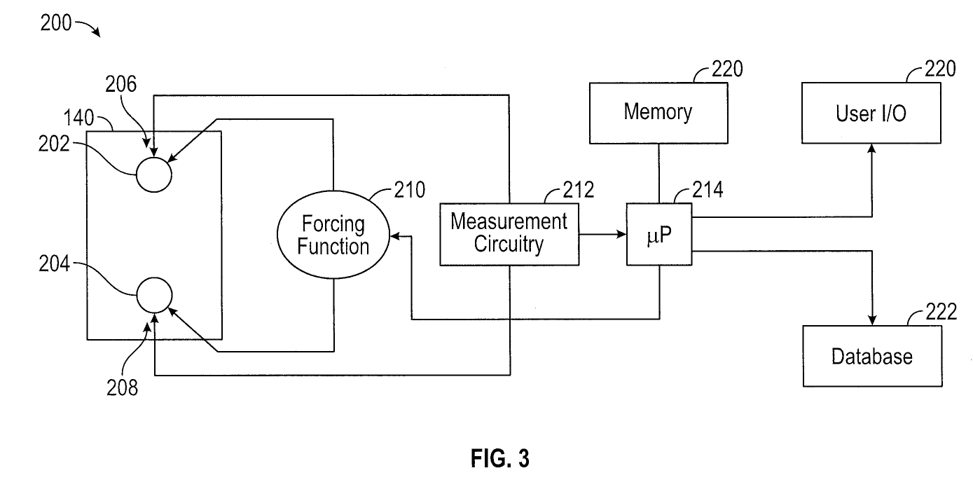

FIG. 3 is a simplified block diagram of a battery pack maintenance device 200 for performing maintenance on battery pack 102. FIG. 3 shows one example of battery test circuitry, in FIG. 3 maintenance device 200 is shown coupled to battery 140 having a positive terminal 202 and a negative terminal 204. A connection 206 is provided to terminal 202 and a similar connector 208 is provided to terminal 204. The connectors 204 and 206 are illustrated as Kelvin connectors, however, the invention is not limited to this configuration. Through connections 206 and 208, a forcing function 210 is coupled to battery 140. The forcing function applies a forcing function signal to the battery 140. The forcing function signal may have a time varying component and may be an active signal in which an electrical signal is injected into the battery or maybe a passive signal in which a current is drawn from the battery. Measurement circuitry 212 is configured to measure a response to the battery 140 to the applied forcing function signal from the forcing function 210. Measurement circuitry 212 provides a measurement signal to microprocessor 214. Microprocessor 214 operates in accordance with instructions stored in memory 220. Memory 220 may also be configured to contain parameters measured from battery 140. A user input/output circuitry 220 is provided for use by an operator. Further, the device 200 is configured to store data in database 220. The battery testing may be optionally performed in accordance with techniques pioneered by Midtronics, Inc. of Willowbrook, Ill., and Dr. Keith S. Champlin, including for example, those discussed in U.S. Pat. No. 3,873,911, issued Mar. 25, 1975, to Champlin; U.S. Pat. No. 3,909,708, issued Sep. 30, 1975, to Champlin; U.S. Pat. No. 4,816,768, issued Mar. 28, 1989, to Champlin; U.S. Pat. No. 4,825,170, issued Apr. 25, 1989, to Champlin; U.S. Pat. No. 4,881,038, issued Nov. 14, 1989, to Champlin; U.S. Pat. No. 4,912,416, issued Mar. 27, 1990, to Champlin; U.S. Pat. No. 5,140,269, issued Aug. 18, 1992, to Champlin; U.S. Pat. No. 5,343,380, issued Aug. 30, 1994; U.S. Pat. No. 5,572,136, issued Nov. 5, 1996; U.S. Pat. No. 5,574,355, issued Nov. 12, 1996; U.S. Pat. No. 5,583,416, issued Dec. 10, 1996; U.S. Pat. No. 5,585,728, issued Dec. 17, 1996; U.S. Pat. No. 5,589,757, issued Dec. 31, 1996; U.S. Pat. No. 5,592,093, issued Jan. 7, 1997; U.S. Pat. No. 5,598,098, issued Jan. 28, 1997; U.S. Pat. No. 5,656,920, issued Aug. 12, 1997; U.S. Pat. No. 5,757,192, issued May 26, 1998; U.S. Pat. No. 5,821,756, issued Oct. 13, 1998; U.S. Pat. No. 5,831,435, issued Nov. 3, 1998; U.S. Pat. No. 5,871,858, issued Feb. 16, 1999; U.S. Pat. No. 5,914,605, issued Jun. 22, 1999; U.S. Pat. No. 5,945,829, issued Aug. 31, 1999; U.S. Pat. No. 6,002,238, issued Dec. 14, 1999; U.S. Pat. No. 6,037,751, issued Mar. 14, 2000; U.S. Pat. No. 6,037,777, issued Mar. 14, 2000; U.S. Pat. No. 6,051,976, issued Apr. 18, 2000; U.S. Pat. No. 6,081,098, issued Jun. 27, 2000; U.S. Pat. No. 6,091,245, issued Jul. 18, 2000; U.S. Pat. No. 6,104,167, issued Aug. 15, 2000; U.S. Pat. No. 6,137,269, issued Oct. 24, 2000; U.S. Pat. No. 6,163,156, issued Dec. 19, 2000; U.S. Pat. No. 6,172,483, issued Jan. 9, 2001; U.S. Pat. No. 6,172,505, issued Jan. 9, 2001; U.S. Pat. No. 6,222,369, issued Apr. 24, 2001; U.S. Pat. No. 6,225,808, issued May 1, 2001; U.S. Pat. No. 6,249,124, issued Jun. 19, 2001; U.S. Pat. No. 6,259,254, issued Jul. 10, 2001; U.S. Pat. No. 6,262,563, issued Jul. 17, 2001; U.S. Pat. No. 6,294,896, issued Sep. 25, 2001; U.S. Pat. No. 6,294,897, issued Sep. 25, 2001; U.S. Pat. No. 6,304,087, issued Oct. 16, 2001; U.S. Pat. No. 6,310,481, issued Oct. 30, 2001; U.S. Pat. No. 6,313,607, issued Nov. 6, 2001; U.S. Pat. No. 6,313,608, issued Nov. 6, 2001; U.S. Pat. No. 6,316,914, issued Nov. 13, 2001; U.S. Pat. No. 6,323,650, issued Nov. 27, 2001; U.S. Pat. No. 6,329,793, issued Dec. 11, 2001; U.S. Pat. No. 6,331,762, issued Dec. 18, 2001; U.S. Pat. No. 6,332,113, issued Dec. 18, 2001; U.S. Pat. No. 6,351,102, issued Feb. 26, 2002; U.S. Pat. No. 6,359,441, issued Mar. 19, 2002; U.S. Pat. No. 6,363,303, issued Mar. 26, 2002; U.S. Pat. No. 6,377,031, issued Apr. 23, 2002; U.S. Pat. No. 6,392,414, issued May 21, 2002; U.S. Pat. No. 6,417,669, issued Jul. 9, 2002; U.S. Pat. No. 6,424,158, issued Jul. 23, 2002; U.S. Pat. No. 6,441,585, issued Aug. 17, 2002; U.S. Pat. No. 6,437,957, issued Aug. 20, 2002; U.S. Pat. No. 6,445,158, issued Sep. 3, 2002; U.S. Pat. No. 6,456,045; U.S. Pat. No. 6,466,025, issued Oct. 15, 2002; U.S. Pat. No. 6,465,908, issued Oct. 15, 2002; U.S. Pat. No. 6,466,026, issued Oct. 15, 2002; U.S. Pat. No. 6,469,511, issued Nov. 22, 2002; U.S. Pat. No. 6,495,990, issued Dec. 17, 2002; U.S. Pat. No. 6,497,209, issued Dec. 24, 2002; U.S. Pat. No. 6,507,196, issued Jan. 14, 2003; U.S. Pat. No. 6,534,993; issued Mar. 18, 2003; U.S. Pat. No. 6,544,078, issued Apr. 8, 2003; U.S. Pat. No. 6,556,019, issued Apr. 29, 2003; U.S. Pat. No. 6,566,883, issued May 20, 2003; U.S. Pat. No. 6,586,941, issued Jul. 1, 2003; U.S. Pat. No. 6,597,150, issued Jul. 22, 2003; U.S. Pat. No. 6,621,272, issued Sep. 16, 2003; U.S. Pat. No. 6,623,314, issued Sep. 23, 2003; U.S. Pat. No. 6,633,165, issued Oct. 14, 2003; U.S. Pat. No. 6,635,974, issued Oct. 21, 2003; U.S. Pat. No. 6,696,819, issued Feb. 24, 20144; U.S. Pat. No. 6,707,303, issued Mar. 16, 2004; U.S. Pat. No. 6,737,831, issued May 18, 2004; U.S. Pat. No. 6,744,149, issued Jun. 1, 2004; U.S. Pat. No. 6,759,849, issued Jul. 6, 2004; U.S. Pat. No. 6,781,382, issued Aug. 24, 2004; U.S. Pat. No. 6,788,025, filed Sep. 7, 2004; U.S. Pat. No. 6,795,782, issued Sep. 21, 2004; U.S. Pat. No. 6,805,090, filed Oct. 19, 2004; U.S. Pat. No. 6,806,716, filed Oct. 19, 2004; U.S. Pat. No. 6,850,037, filed Feb. 1, 2005; U.S. Pat. No. 6,850,037, issued Feb. 1, 2005; U.S. Pat. No. 6,871,151, issued Mar. 22, 2005; U.S. Pat. No. 6,885,195, issued Apr. 26, 2005; U.S. Pat. No. 6,888,468, issued May 3, 2005; U.S. Pat. No. 6,891,378, issued May 10, 2005; U.S. Pat. No. 6,906,522, issued Jun. 14, 2005; U.S. Pat. No. 6,906,523, issued Jun. 14, 2005; U.S. Pat. No. 6,909,287, issued Jun. 21, 2005; U.S. Pat. No. 6,914,413, issued Jul. 5, 2005; U.S. Pat. No. 6,913,483, issued Jul. 5, 2005; U.S. Pat. No. 6,930,485, issued Aug. 16, 2005; U.S. Pat. No. 6,933,727, issued Aug. 23, 200; U.S. Pat. No. 6,941,234, filed Sep. 6, 2005; U.S. Pat. No. 6,967,484, issued Nov. 22, 2005; U.S. Pat. No. 6,998,847, issued Feb. 14, 2006; U.S. Pat. No. 7,003,410, issued Feb. 21, 2006; U.S. Pat. No. 7,003,411, issued Feb. 21, 2006; U.S. Pat. No. 7,012,433, issued Mar. 14, 2006; U.S. Pat. No. 7,015,674, issued Mar. 21, 2006; U.S. Pat. No. 7,034,541, issued Apr. 25, 2006; U.S. Pat. No. 7,039,533, issued May 2, 2006; U.S. Pat. No. 7,058,525, issued Jun. 6, 2006; U.S. Pat. No. 7,081,755, issued Jul. 25, 2006; U.S. Pat. No. 7,106,070, issued Sep. 12, 2006; U.S. Pat. No. 7,116,109, issued Oct. 3, 2006; U.S. Pat. No. 7,119,686, issued Oct. 10, 2006; and U.S. Pat. No. 7,126,341, issued Oct. 24, 2006; U.S. Pat. No. 7,154,276, issued Dec. 26, 2006; U.S. Pat. No. 7,198,510, issued Apr. 3, 2007; U.S. Pat. No. 7,363,175, issued Apr. 22, 2008; U.S. Pat. No. 7,208,914, issued Apr. 24, 2007; U.S. Pat. No. 7,246,015, issued Jul. 17, 2007; U.S. Pat. No. 7,295,936, issued Nov. 13, 2007; U.S. Pat. No. 7,319,304, issued Jan. 15, 2008; U.S. Pat. No. 7,363,175, issued Apr. 22, 2008; U.S. Pat. No. 7,398,176, issued Jul. 8, 2008; U.S. Pat. No. 7,408,358, issued Aug. 5, 2008; U.S. Pat. No. 7,425,833, issued Sep. 16, 2008; U.S. Pat. No. 7,446,536, issued Nov. 4, 2008; U.S. Pat. No. 7,479,763, issued Jan. 20, 2009; U.S. Pat. No. 7,498,767, issued Mar. 3, 2009; U.S. Pat. No. 7,501,795, issued Mar. 10, 2009; U.S. Pat. No. 7,505,856, issued Mar. 17, 2009; U.S. Pat. No. 7,545,146, issued Jun. 9, 2009; U.S. Pat. No. 7,557,586, issued Jul. 7, 2009; U.S. Pat. No. 7,595,643, issued Sep. 29, 2009; U.S. Pat. No. 7,598,699, issued Oct. 6, 2009; U.S. Pat. No. 7,598,744, issued Oct. 6, 2009; U.S. Pat. No. 7,598,743, issued Oct. 6, 2009; U.S. Pat. No. 7,619,417, issued Nov. 17, 2009; U.S. Pat. No. 7,642,786, issued Jan. 5, 2010; U.S. Pat. No. 7,642,787, issued Jan. 5, 2010; U.S. Pat. No. 7,656,162, issued Feb. 2, 2010; U.S. Pat. No. 7,688,074, issued Mar. 30, 2010; U.S. Pat. No. 7,705,602, issued Apr. 27, 2010; U.S. Pat. No. 7,706,992, issued Apr. 27, 2010; U.S. Pat. No. 7,710,119, issued May 4, 2010; U.S. Pat. No. 7,723,993, issued May 25, 2010; U.S. Pat. No. 7,728,597, issued Jun. 1, 2010; U.S. Pat. No. 7,772,850, issued Aug. 10, 2010; U.S. Pat. No. 7,774,151, issued Aug. 10, 2010; U.S. Pat. No. 7,777,612, issued Aug. 17, 2010; US. Pat. No. 7,791,348, issued Sep. 7, 2010; U.S. Pat. No. 7,808,375, issued Oct. 5, 2010; U.S. Pat. No. 7,924,015, issued Apr. 12, 2011; U.S. Pat. No. 7,940,053, issued May 10, 2011; U.S. Pat. No. 7,940,052, issued May 10, 2011; U.S. Pat. No. 7,959,476, issued Jun. 14, 2011; U.S. Pat. No. 7,977,914, issued Jul. 12, 2011; U.S. Pat. No. 7,999,505, issued Aug. 16, 2011; U.S. Pat. No. D643,759, issued Aug. 23, 2011; U.S. Pat. No. 8,164,343, issued Apr. 24, 2012; U.S. Pat. No. 8,198,900, issued Jun. 12, 2012; U.S. Pat. No. 8,203,345, issued Jun. 19, 2012; U.S. Pat. No. 8,237,448, issued Aug. 7, 2012; U.S. Pat. No. 8,306,690, issued Nov. 6, 2012; U.S. Pat. No. 8,344,685, issued Jan. 1, 2013; U.S. Pat. No. 8,436,619, issued May 7, 2013; U.S. Pat. No. 8,442,877, issued May 14, 2013; U.S. Pat. No. 8,493,022, issued Jul. 23, 2013; U.S. Pat. No. D687,727, issued Aug. 13, 2013; U.S. Pat. No. 8,513,949, issued Aug. 20, 2013; U.S. Pat. No. 8,674,654, issued Mar. 18, 2014; U.S. Pat. No. 8,674,711, issued Mar. 18, 2014; U.S. Pat. No. 8,704,483, issued Apr. 22, 2014; U.S. Pat. No. 8,738,309, issued May 27, 2014; U.S. Pat. No. 8,754,653, issued Jun. 17, 2014; U.S. Pat. No. 8,872,516, issued Oct. 28, 2014; U.S. Pat. No. 8,872,517, issued Oct. 28, 2014; U.S. Pat. No. 8,958,998, issued Feb. 17, 2015; U.S. Pat. No. 8,963,550, issued Feb. 24, 2015; U.S. Pat. No. 9,018,958, issued Apr. 28, 2015; U.S. Pat. No. 9,052,366, issued Jun. 9, 2015; U.S. Pat. No. 9,201,120, issued Dec. 1, 2015; U.S. Pat. No. 9,229,062, issued Jan. 5, 2016; U.S. Pat. No. 9,274,157, issued Mar. 1, 2016; U.S. Pat. No. 9,312,575, issued Apr. 12, 2016; U.S. Pat. No. 9,335,362, issued May 10, 2016; U.S. Pat. No. 9,425,487, issued Aug. 23, 2016;U.S. Pat. No. 9,419,311, issued Aug. 16, 2016; U.S. Pat. No. 9,496,720, issued Nov. 15, 2016; U.S. Pat. No. 9,588,185, issued Mar. 7, 2017; U.S. Pat. No. 9,923,289, issued Mar. 20, 2018; U.S. Pat. No. 9,966,676, issued May 8, 2018; U.S. Pat. No. 10,046,649; U.S. Ser. No. 09/780,146, filed Feb. 9, 2001, entitled STORAGE BATTERY WITH INTEGRAL BATTERY TESTER; U.S. Ser. No. 09/756,638, filed Jan. 8, 2001, entitled METHOD AND APPARATUS FOR DETERMINING BATTERY PROPERTIES FROM COMPLEX IMPEDANCE/ADMITTANCE; U.S. Ser. No. 09/862,783, filed May 21, 2001, entitled METHOD AND APPARATUS FOR TESTING CELLS AND BATTERIES EMBEDDED IN SERIES/PARALLEL SYSTEMS; U.S. Ser. No. 09/880,473, filed Jun. 13, 2001; entitled BATTERY TEST MODULE; U.S. Ser. No. 10/109,734, filed Mar. 28, 2002, entitled APPARATUS AND METHOD FOR COUNTERACTING SELF DISCHARGE IN A STORAGE BATTERY; U.S. Ser. No. 10/263,473, filed Oct. 2, 2002, entitled ELECTRONIC BATTERY TESTER WITH RELATIVE TEST OUTPUT; U.S. Ser. No. 09/653,963, filed Sep. 1, 2000, entitled SYSTEM AND METHOD FOR CONTROLLING POWER GENERATION AND STORAGE; U.S. Ser. No. 10/174,110, filed Jun. 18, 2002, entitled DAYTIME RUNNING LIGHT CONTROL USING AN INTELLIGENT POWER MANAGEMENT SYSTEM; U.S. Ser. No. 10/258,441, filed Apr. 9, 2003, entitled CURRENT MEASURING CIRCUIT SUITED FOR BATTERIES; U.S. Ser. No. 10/681,666, filed Oct. 8, 2003, entitled ELECTRONIC BATTERY TESTER WITH PROBE LIGHT; U.S. Ser. No. 11/207,419, filed Aug. 19, 2005, entitled SYSTEM FOR AUTOMATICALLY GATHERING BATTERY INFORMATION FOR USE DURING BATTERY TESTER/CHARGING, U.S. Ser. No. 11/356,443, filed Feb. 16, 2006, entitled ELECTRONIC BATTERY TESTER WITH NETWORK COMMUNICATION; U.S. Ser. No. 12/697,485, filed Feb. 1, 2010, entitled ELECTRONIC BATTERY TESTER; U.S. Ser. No. 12/769,911, filed Apr. 29, 2010, entitled STATIONARY BATTERY TESTER; U.S. Ser. No. 13/098,661, filed May 2, 2011, entitled METHOD AND APPARATUS FOR MEASURING A PARAMETER OF A VEHICLE ELECTRICAL SYSTEM; U.S. Ser. No. 13/152,711, filed Jun. 3, 2011, entitled BATTERY PACK MAINTENANCE FOR ELECTRIC VEHICLE; U.S. Ser. No. 13/672,186, filed Nov. 8, 2012, entitled BATTERY PACK TESTER; U.S. Ser. No. 14/039,746, filed Sep. 27, 2013, entitled BATTERY PACK MAINTENANCE FOR ELECTRIC VEHICLE; U.S. Ser. No. 14/204,286, filed Mar. 11, 2014, entitled CURRENT CLAMP WITH JAW CLOSURE DETECTION; U.S. Ser. No. 14/565,689, filed Dec. 10, 2014, entitled BATTERY TESTER AND BATTERY REGISTRATION TOOL; U.S. Ser. No. 14/799,120, filed Jul. 14, 2015, entitled AUTOMOTIVE MAINTENANCE SYSTEM; U.S. Ser. No. 14/861,027, filed Sep. 22, 2015, entitled CABLE CONNECTOR FOR ELECTRONIC BATTERY TESTER; U.S. Ser. No. 15/006,467, filed Jan. 26, 2016, entitled ALTERNATOR TESTER; U.S. Ser. No. 15/017,887, filed Feb. 8, 2016, entitled METHOD AND APPARATUS FOR MEASURING A PARAMETER OF A VEHICLE ELECTRICAL SYSTEM; U.S. Ser. No. 15/049,483, filed Feb. 22, 2016, entitled BATTERY TESTER FOR ELECTRIC VEHICLE; U.S. Ser. No. 15/077,975, filed Mar. 23, 2016, entitled BATTERY MAINTENANCE SYSTEM; U.S. Ser. No. 15/140,820, filed Apr. 28, 2016, entitled CALIBRATION AND PROGRAMMING OF IN-VEHICLE BATTERY SENSOR; U.S. Ser. No. 15/149,579, filed May 9, 2016, entitled BATTERY TESTER FOR ELECTRIC VEHICLE; U.S. Ser. No. 15/634,491, filed Jun. 27, 2017, entitled BATTERY CLAMP; U.S. Ser. No. 15/791,772, field Oct. 24, 2017, entitled ELECTRICAL LOAD FOR ELECTRONIC BATTERY TESTER AND ELECTRONIC BATTERY TESTER INCLUDING SUCH ELECTRICAL LOAD; U.S. Ser. No. 16/021,538, filed Jun. 28, 2018, entitled BATTERY PACK MAINTENANCE FOR ELECTRIC VEHICLE; U.S. Ser. No. 16/056,991, filed Aug. 7, 2018, entitled HYBRID AND ELECTRIC VEHICLE BATTERY PACK MAINTENANCE DEVICE, all of which are incorporated herein by reference in their entireties.

During operation, device 200 is capable of measuring a parameter of battery 140 through the Kelvin connections 206 and 208. For example, a forcing function can be applied by forcing function 210. Measurement circuitry 212 can monitor the effect of the applied forcing function signal on the battery 140 and responsively provide an output to microprocessor 214. This can be used to measure a dynamic parameter of the battery such as dynamic conductance, etc. The present invention is not limited to this particular testing method and other techniques may also be employed. Further, the testing of battery 140 or group of batteries 140 may be performed using sensors within battery pack 102. In such a configuration, the testing may be performed without disassembling the battery pack 102. Microprocessor 214 can operate in accordance with programming instructions stored in memory 220. Memory 220 can also store information by microprocessor 214. Operation of device 200 can be controlled by user I/O 220 which can comprise, for example, a manual input such as a keyboard and/or an output such as a display. Measured parameters of battery can be stored in database 222 for subsequent retrieval. Further, in some configurations, the forcing function 210 can include a load for discharging the battery 140 and/or a power supply for charging battery 140. This can be used to balance the batteries 140 within the battery pack 102.

It is desirable to provide a tool that can service a wide range of electric vehicle battery modules, and be future-proof for modules as yet un-defined. It is further desirable to build such a unit out of commercially available “building blocks” to simplify the design and certification process. In one such embodiment, three 48 VDC @ 20 ampere electronically adjustable power supplies connected together in various configurations are provided. The choice of voltage, amperage, and number of blocks is arbitrary and other such arrangements are provided. For higher voltage, the power supplies can be connected in series, and for higher current the power supplies can be connected in parallel. While this can be accomplished in several ways using relays and switches, in one embodiment it can simply and inexpensively be accomplished in the battery connection cables as shown below.

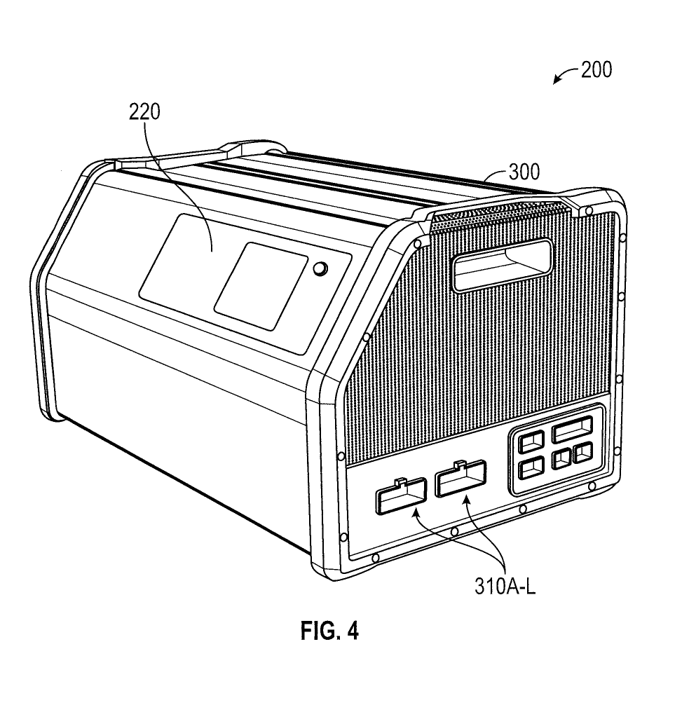

FIG. 4 is a perspective view showing a housing 300 of maintenance device 200. FIG. 4 illustrates cable connectors 310A-L for use as described below in selecting a voltage/current output as well as providing connections to the battery under test 140.

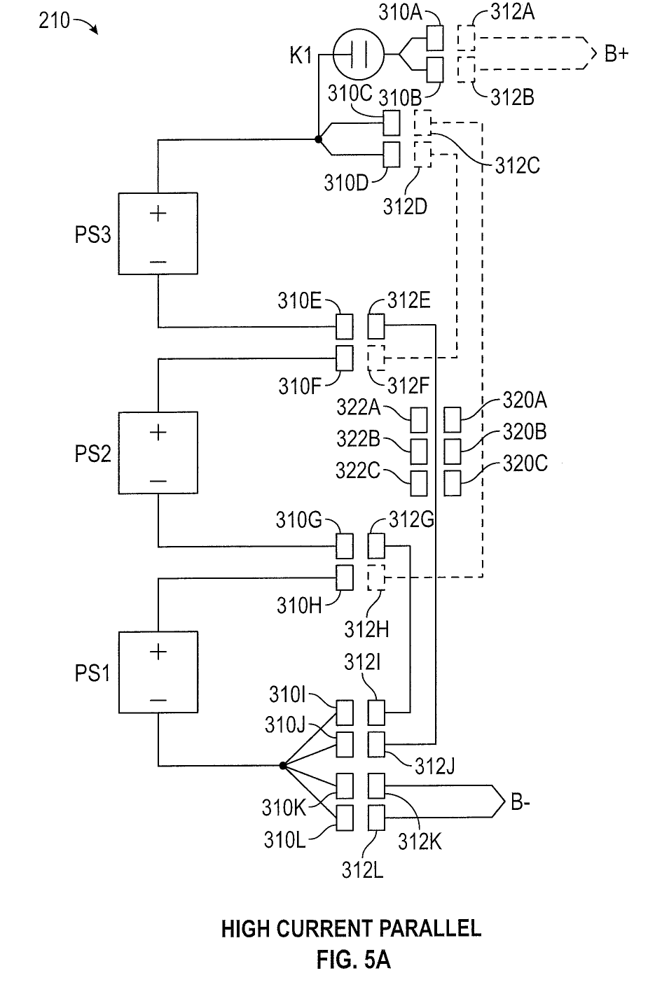

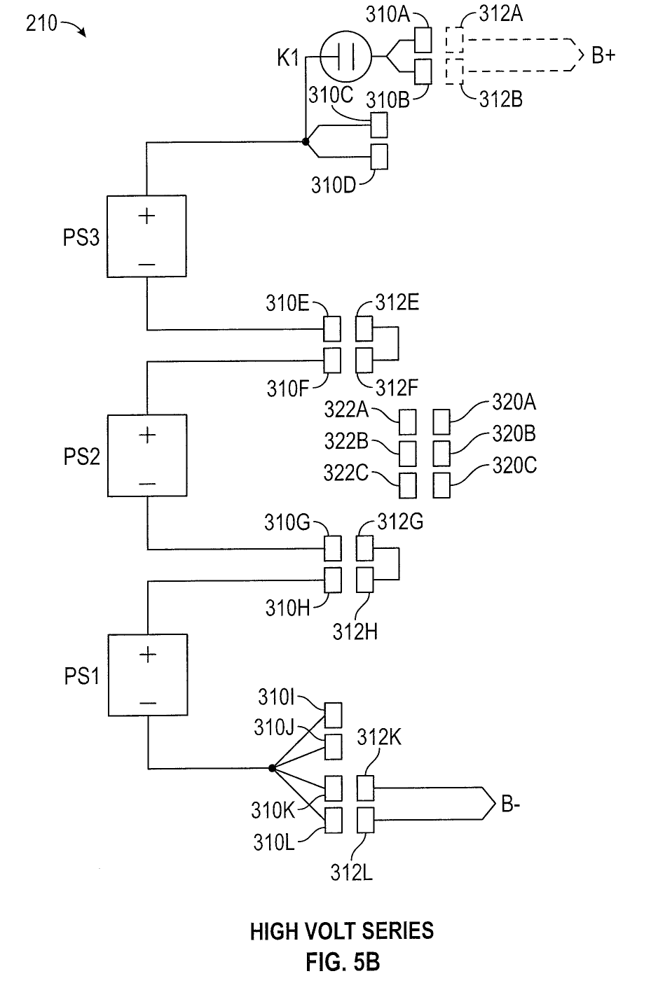

FIGS. 5A and 5B show example configurations of forcing function 210 arranged to apply different current levels and/or voltage levels to the battery 140 using a plug configuration which allows various connections between the power supply units. As illustrated in FIGS. 5A and 5B, three power supplies are shown PS1, PS2 and PS3. Power supplies PS1-3 are electrically connected to connectors 310A-L as illustrated in the Figures. By selectively applying jumpers between these connectors, various power supply voltage and current configurations can be obtained. B+and B- connections are used to provide Kelvin connections to the battery 140. Cable connectors 312A-L selectively plug into connectors 310A-L. External jumpers are provided to select the desired voltage and/or current levels provided by the power supplies. In the configuration illustrated in FIG. 5A, the power supplies are connected in parallel to thereby deliver a high current value at the voltage of the power supplies. FIG. 5B shows another example configuration in which jumpers are provided between connectors 312 to achieve a series connection such that the power supplies PS1-3 are stacked to provide triple the voltage of an individual power supply. An emergency shut off relay K1 is provided which allows the power supplies to be quickly disconnected from the battery 140. Relay K1 can be operated manually, or based upon some input such as an excessive temperature, current or voltage measurement, under the control of microprocessor 214, or by some other means.

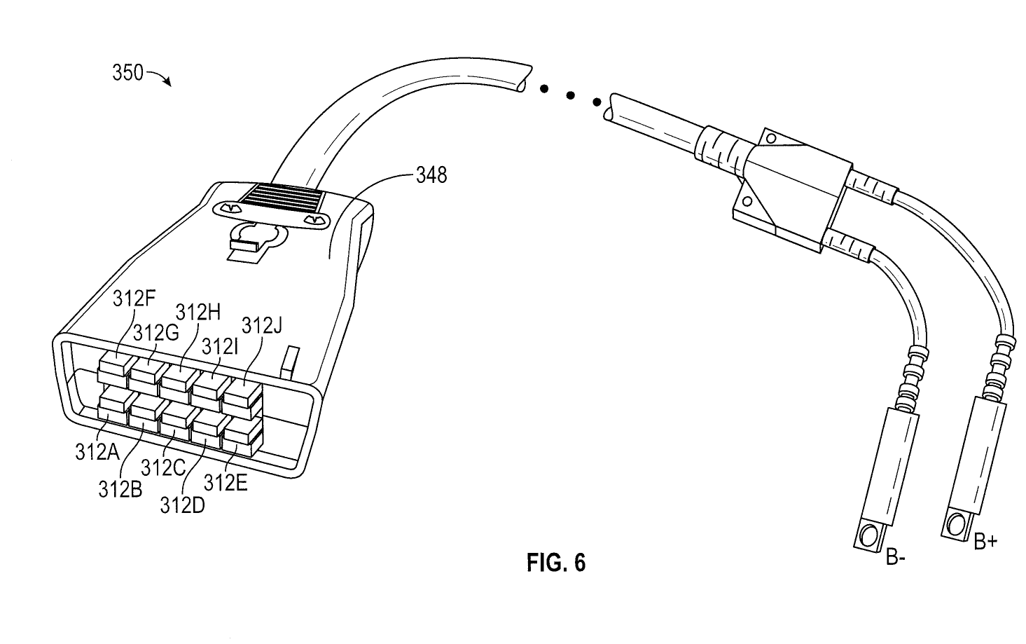

FIGS. 5A and 5B also show magnets 320A, B and C. These magnets are carried in a plug (see element 348 in FIG. 6) and can be used to encode the configuration of the jumpers carried between connectors 312. Magnetic sensors 322A, B and C are arranged in the maintenance device 200 and configured to sense the presence of magnets 320A-C, respectively. This information can be used by microprocessor to determine the configuration of the power supplies provided by the jumpers. For example, in FIG. 5A, three magnets 320A, B and C are provided whereas in FIG. 5B only magnets 320A and B are provided.

In both the parallel or serial arrangement, the units are designed to be connected either in parallel or series externally by the technician for even greater capability in the future.

FIG. 6 is a perspective view of an example cable 350 configuration in which a plug or shell 348 carries connectors 312A-L. As discussed with respect to FIGS. 5A and B, these connectors can be used to selectively configure the coupling between the various power supplies. The cable further provides electrical connections to the B+ and B− connectors for coupling to the battery under test 140.

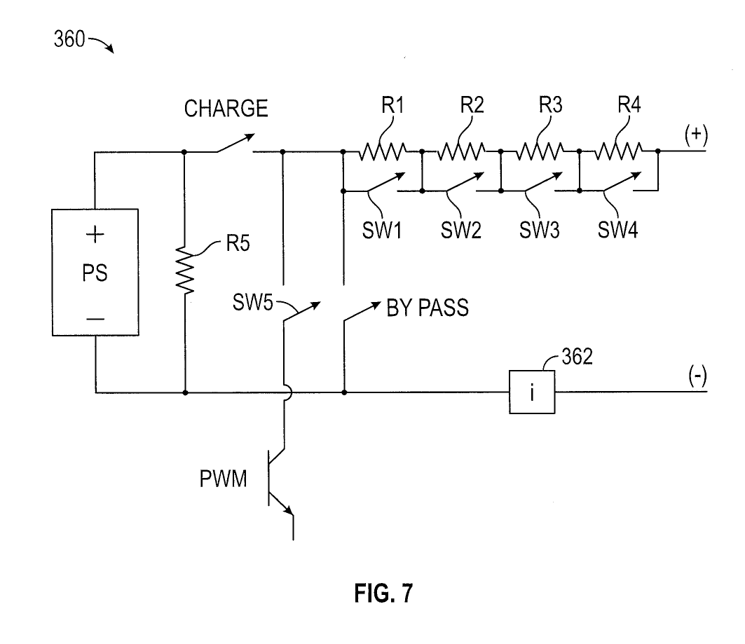

Each of the power supply sections PS1-3 may also optionally contain a discharge function such as illustrated in FIG. 7. When servicing electric vehicle batteries, it may be necessary to charge or discharge the modules. One method uses resistor load elements, relays, and transistors to vary the discharge current, whether in high current parallel mode, or high voltage series mode. As an additional benefit, this resistor array can be configured to provide loop stability ballast when the power supplies are connected in parallel and charging as shown in FIG. 5A.

FIG. 7 illustrates a resistor array 360 connected to a Power Supply. In the configuration of FIG. 7, resistors R1, R2, R3 and R4 are arranged in series along with parallel switches SW1, SW2, SW3 and SW4. The charge switch is provided which connects power supply to the battery plus/minus connections. A bypass switch is provided which allows the Power supply PS to be bypassed. Further, a switch SW5 is provided to electrically connect a transistor PWM in series with the resistor R1-4. The current sensors 362 can be used to measure the current flowing through the array 360. Resistor R5 is used to provide a minimum load for the power supply. In some cases, this may be required with a switched mode power supply. Further, it can be used for a rapid bleed off of voltages when the power supply is switched off. Switch SW5 is used to engage the discharge portion of the device which is controlled by the TWM transistor. SW5 is open during charging and then closed during discharge. However, switch SW5 can also be closed during charging to provide a self-test function by internally loading the power supply. The switches can be operated under the control of microprocessor 214 used to selectively apply a load for discharging the battery 140.

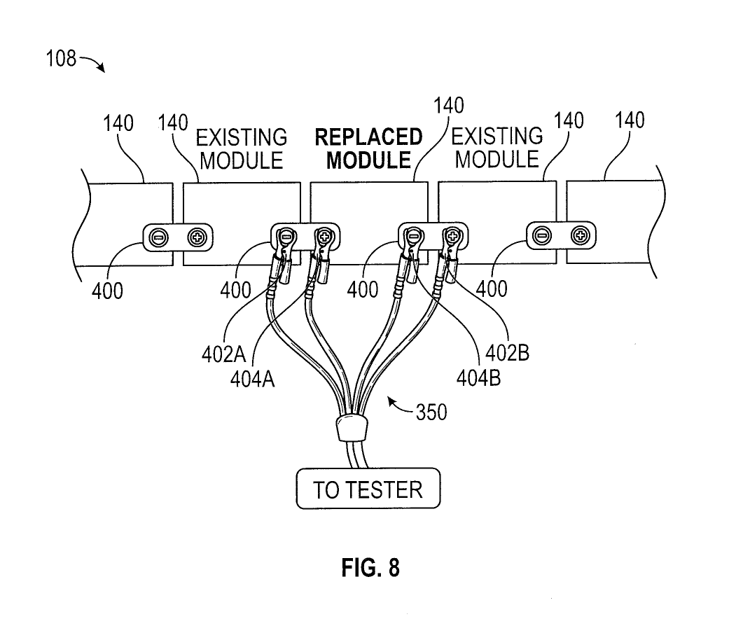

It can be very time consuming to remove an electric vehicle battery pack from the vehicle, open it up, remove the defective modules, balance the replacement module, reinstall the module into the pack, and reinstall the pack into the vehicle. If the battery is not reinstalled correctly with the proper torques, etc., the entire process must be repeated. To address this issue, the device can also be used to test the resistance of the battery pack to detect problems with, for example, the “bus bars” 400 shown in FIG. 8 that are used to connect the batteries 140 within the pack 102. The test can be used after the battery module 140 is reinstalled into the pack 102. A six wire Kelvin connection is used in the preferred embodiment. Leads 402 are Kelvin connections and the current carrying leads can carry 50-75 amps. Leads 404 are voltage sense only. In order to perform a measurement, a large current is applied through Kelvin connectors 402 while voltage measurements are taken. A voltage measurement using a differential amplifier is made across connectors 402A and 404A and a similar measurement is obtained across connectors 402B and 404B. A third differential voltage measurement is made between the 404A and 404B. The measurements can be made, for example, using measurement circuitry 212 shown in FIG. 3. This allows the resistances of all components to be measured in a single step. In another example embodiment, an operator could move the connections moving leads and taking multiple voltage readings. Conductance can also be determined. A high current pulse is established across the extremities of the connection (for example, using forcing function 210), and individual voltage drops are recorded across all connections. The battery, the positive connection, and the negative connection can then be evaluated.

Note that this measurement may somewhat disturb the battery equilibrium. To counter act this, balance in the battery pack can be restored by applying an equal and opposite charge back into the system. There is also significant battery health diagnostic information to be gleaned from lithium battery cells using this technique and can also be used to test battery module before returning it to service.

In one aspect, the device can connect to the vehicle data bus through the OBDII connection to collect important information such as VIN, software and hardware version numbers, etc. Connection to the battery ECU can be made using CAN, LIN, or other protocols to glean specific battery infoiination.

One preferred embodiment uses a powerful operating system such as Android. This allows detailed photographs, drawings, training videos and other helpful information to be displayed. It allows for a simplified “cloud” connection to update latest service bulletins, software updates, record keeping, legal traceability, warranty adjudication and countless other benefits. The unit can be connected as a slave to another piece of shop equipment, either by hardwired connection, or wireless such as Bluetooth or Wi-Fi. Components in the unit can be protected against reverse polarity, or over-voltage. Safeties, including electrical potential, temperature, access points, etc. are fully interlocked and prevent operation of the unit. Cables may contain a “poke yoke” scheme that prevents the wrong cable from being used; for example, a high voltage series cable in a high current parallel application. An optional bar code scanner is available which can capture specific information such as battery type or serial number, vehicle identification number, etc. The various inputs and outputs can be through a general input/output interface 220.

This unit is designed to operate at high power levels, but may be attached to AC mains as low as 100VAC to as high as 240VAC. The unit is capable of monitoring the input mains current so that power can be throttled back when operating at low line voltages and the required power is not available from the AC mains.

The unit can operate in any combination of constant voltage, constant current, or constant power. A remote temperature sensor can be used that can plug into the balancer and report the battery temperature. This is useful when internal battery temperature sensors are damaged or inoperative, or the module is removed from the pack and no sensors are available. Optional relay contacts available to the external world to control various circuits on the battery pack. Optional voltage sensing lines can be provided to monitor various circuits on the battery pack. Internal circuitry can be used to perform a conductance or impedance test on the module.

It is programmable to any frequency, and can be applied at variable amplitude. A full timed discharge can be performed on the module to accurately report amp-hour capacity. This test can be performed at variable rates. The device has the ability to recharge back to a specified state of charge. A charge acceptance test can be performed on the battery at variable rates and times. This same unit can be used to evaluate 48 volt cranking batteries, of any chemistry including lithium or lead acid.

Input/output circuitry 220 is provided for use in physically connecting to a data communication link such as an RS232, USB connection, Ethernet, etc. Optionally, wireless I/O is also provided for use in communicating in accordance with wireless technologies such as WiFi techniques, Bluetooth®, Zigbee®, etc. Other, examples include the CAN communication protocol, OBDII, etc.

As discussed above, in one aspect the maintenance device can be configured to “balance” individual cells within the battery pack. The balancing can be performed by selecting cells or individual batteries within the pack which have similar storage capacity and state of charge. The charging feature of the device can be used to increase the charge of a cell or battery to that of other cells or batteries. Similarly, the maintenance device can be used to discharge individual cells or batteries to a level similar to that of other cells or batteries within the pack.

During discharge of the battery pack, the discharge profile can be monitored to ensure proper operation. For example, if the voltage of the battery suddenly drops, this can be an indication that a component within the battery has failed or a short circuit has occurred.

The charging circuitry of the device can use a stacked switch mode power supply configuration. For example, a series of fixed voltage power supplies can be stacked with the base power supply having an adjustable voltage output. This configuration allows a continuous controllability of the voltage output from the stacked power supply by turning one supply on at a time and providing finer control with the adjustable power supply. Further, the use of a stacked power supply can be used to reduce the current inrush when the power supply is activated. More specifically, individual supplies in the stacked power supply can be turned on sequentially to reduce the instantaneous current inrush. Additionally, current limiters can be used to reduce the current inrush. Diodes can be configured across the outputs of each power supply in such that they are configured to not conduct. The diodes can be used to prevent back feeding of the power supply from the battery pack.

Although the present invention has been described with reference to preferred embodiments, workers skilled in the art will recognize that changes may be made in form and detail without departing from the spirit and scope of the invention.

What is claimed is:

1. An apparatus for balancing charge of a battery in a battery pack, comprising:
a plurality of power supplies configured to be selectively coupled to the battery;
a plurality of electrical loads configured to be electrically coupled to the battery;
test circuitry configured to measure an amount of charge of the battery; and
control circuitry configured to selectively control a voltage applied to the battery by the plurality of power supplies and a load applied to the battery by the plurality of electrical loads based upon a measured amount of charge of the battery.

2. The apparatus of claim 1 wherein the plurality of electrical power supplies are configured to be connected in series.

3. The apparatus of claim 1 wherein the plurality of electrical power supplies are configured to be connected in parallel.

4. The apparatus of claim 1 wherein the plurality of electrical loads are configured to be connected in series.

5. The apparatus of claim 1 wherein the plurality of electrical loads are configured to be connected in parallel.

6. The apparatus of claim 1 including a plug for electrically connecting the plurality of power supplies to the battery, wherein the plug is configured to connect the power supplies in series.

7. The apparatus of claim 1 including a plug for electrically connecting the plurality of power supplies to the battery, wherein the plug is configured to connect the power supplies in parallel.

8. The apparatus of claim 1 including a housing configured to house the plurality of power supplies and wherein the housing includes a plurality of connectors configured to couple to a plug whereby the power supplies are connected in series or parallel.

9. The apparatus of claim 8 wherein the plug provides Kelvin connectors to the battery.

10. The apparatus of claim 1 wherein the test circuitry is further configured to measure a resistance of a bus bar of the battery pack.

11. The apparatus of claim 10 wherein the plurality of power supplies that are configured to charge the battery following testing of a resistance of the battery pack.
